(19) United States
(12) Patent Application Publication
(10) Pub. No.: US 2019/0074756 A1
(43) Pub. Date: Mar. 7, 2019

(54) MAGNET ARRAY, ELECTRIC COIL DEVICE, DISPLACEMENT SYSTEM, LITHOGRAPHIC APPARATUS AND DEVICE MANUFACTURING METHOD

(71) Applicant: ASML Netherlands B.V., Veldhoven (NL)

(72) Inventor: Johannes Marinus Maria ROVERS, Eindhoven (NL)

(21) Appl. No.: 15/767,199

(22) PCT Filed: Oct. 4, 2016
(86) PCT No.: PCT/EP2016/073634

§ 371 Date: Apr. 10, 2018

(30) Foreign Application Priority Data
Nov. 5, 2015 (EP) 15193112.8
Dec. 17, 2015 (EP) 15200713.4

(51) Int. Cl. H02K 41/03; G03F 7/20; H02K 1/02

(52) U.S. Cl. CPC H02K 41/031; G03F 7/70758; G03F 7/70775; H02K 1/02; G03F 7/709

(57) ABSTRACT

A magnet array for a displacement device for a displacement system, the magnet array comprising a two dimensional pattern of magnets of a first type and magnets of a second type, whereby magnets of the first type and magnets of the second type have parallel but opposing magnetizing direction and are alternatingly arranged at regular intervals in both a first and a second direction, wherein the first and second directions are not perpendicular to each other; a distance between two adjacent magnets of the same type in a third direction is unequal to a distance between two adjacent magnets of the same type in a fourth direction; and, the third and fourth direction are perpendicular to each other.

### CROSS-REFERENCE TO RELATED APPLICATIONS

This application claims priority of EP application 15193112.8 which was filed on 5 Nov. 2015 and EP application 15200713.4 which was filed on 17 Dec. 2015 and which are incorporated herein in its entirety by reference.

### BACKGROUND

### Field of the Invention

The present invention relates to a magnet array for a displacement system, the magnet array comprising a two dimensional pattern of magnets of a first type and magnets of a second type, whereby magnets of the first type and magnets of the second type have parallel but opposing magnetizing direction and are alternatingly arranged at regular intervals in both a first and a second direction. The invention further relates to an electric coil device for a displacement system, the displacement system itself a lithographic apparatus and a method for manufacturing a device.

### Description of the Related Art

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In a lithographic apparatus displacement of objects, such as a substrate or a patterning device are required. Comparative large displacements in one or two directions and comparative small displacements for accurate positioning are required. The requirements are often realized by combining a long stroke motor capable of displacing an object over comparatively large distances in one or two directions with a short stroke motor comprising one or more linear actuators, capable of displacing an object with high accuracy over comparatively small distances. By mounting the short stroke motor on the long stroke motor, an object that is held by an object table connected to said short stroke motor can both be to displaced over large distances and accurately positioned. A particular example of such a long stroke motor is a planar motor.

A planar motor for a displacement system may comprise a magnet array and an electric coil device, one of the array and device being movable relative to the other of the array and device. For example, the planar motor may have a stationary magnet array and a movable electric coil device comprising a plurality of coils. By applying the appropriate currents to the different coils, forces can be generated between the coil device and the magnet array. Those forces can displace an object table connected to the coil device in a directions parallel to the plane of the magnet array and in direction perpendicular to said plane. In general, the forces parallel to the plane of the magnet array may be applied to displace the object table distances and/or angles in the horizontal plane (X, Y and Rz) while the forces in a direction perpendicular to said plane may be generated to maintain the object table at a predetermined height and inclination (Z, Rx and Ry).

In order to allow displacements in said X-direction and said Y-direction orthogonal to said X-direction over comparatively large distances, the magnet array is designed in such a way that it comprises a two dimensional pattern of magnets of a first type and magnets of a second type, whereby magnets of the first type and magnets of the second type have parallel but opposing magnetizing direction perpendicular to the array and are alternatingly arranged at regular intervals in both a first and a second direction. The first and second directions are perpendicular to each other. A distance between the center of two adjacent magnets of the same type in a third direction is equal to a distance between the center of two adjacent magnets of the same type in a fourth direction. This distance determines the magnetic pitch in the third and fourth direction which is as a consequence also equal. The third and fourth direction are perpendicular to each other and under an angle of 45 degrees with the first and second axis.

### SUMMARY

It is desirable to provide an improved and/or alternative magnetic array.

Accordingly there is provided a magnet array for a displacement system, the magnet array comprising a two dimensional pattern of magnets of a first type and magnets of a second type, whereby magnets of the first type and magnets of the second type have an opposing magnetizing direction substantially perpendicular to a plane of the array and are alternatingly arranged at regular intervals in both a first and a second direction, wherein

the first and second directions are not perpendicular to each other;

to a distance between two adjacent magnets, both of the first type or both of the second type, in a third direction is unequal to a distance between two adjacent magnets, both of the first type or both of the second type, in a fourth direction.

According to a further embodiment there is provided a magnet array for a displacement system, the magnet array comprising a two dimensional pattern of magnets of a first type and magnets of a second type, whereby magnets of the first type and magnets of the second type have an opposing magnetizing direction substantially perpendicular to the array and are alternatingly arranged at regular intervals along parallel first lines in a first direction and parallel second lines in a second direction, wherein a distance between two neighbouring first lines is equal to the distance between two neighbouring second lines and two neighbouring first lines crossing with two neighbouring second lines form a rhombus shape.

According to a further embodiment there is provided a displacement system comprising a first part and a second part which can be displaced with respect to each other in a plane, wherein the first part comprises the magnet array and the second part is provided with an electric coil device comprising:

at least a first electric coil which has a current conductor which is substantially perpendicular to the third direction; and,

at least a second electric coil which has a current conductor which is substantially perpendicular to the fourth direction of the magnet array.

According to a further embodiment there is provided a lithographic apparatus arranged to transfer a pattern from a patterning device onto a substrate, wherein the apparatus comprises the magnet array, the displacement device, and/or the displacement system

According to an embodiment of the invention, there is provided a device manufacturing method comprising transferring a pattern from a patterning device onto a substrate, wherein the method comprises displacing an object table with respect to the patterning device over a plane of a magnet array comprising a two dimensional pattern of magnets of a first type and magnets of a second type, whereby magnets of the first type and magnets of the second type have an opposing magnetizing direction and are alternatingly arranged at regular intervals in both a first and a second direction, the first and second direction being not perpendicular to each other, and a distance between two adjacent magnets of the same type in a third direction to being different from a distance between two adjacent magnets of the same type in a fourth direction, the object table being displaced by providing an electrical current to at least an electric coil provided to the object table which has current conductors which are substantially perpendicular to the third or fourth direction.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts a top view on a magnet array according to an embodiment;

FIG. 3 depicts a top view on the same magnet array of FIG. 2;

FIG. 4 depicts a top view on the same magnet array of FIGS. 2 and 3; and

FIG. 5 depicts an electric coil device for a displacement system for use with the magnet array of FIGS. 2 to 5.

### DETAILED DESCRIPTION

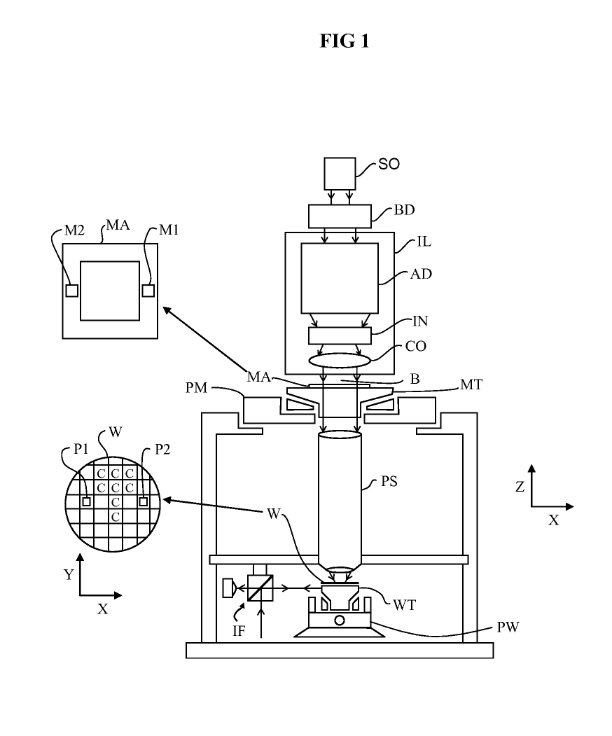

FIG. 1 schematically depicts a lithographic apparatus according to one embodiment of the invention. The apparatus includes an illumination system (illuminator) IL configured to condition a radiation beam B (e.g. UV radiation or any other suitable radiation), a mask support structure (e.g. a mask table) MT constructed to support a patterning device (e.g. a mask) MA and connected to a first positioning system PM configured to accurately position the patterning device in accordance with certain parameters. The apparatus also includes a substrate table (e.g. a wafer table) WT or “substrate support” constructed to hold a substrate (e.g. a resist-coated wafer) W and connected to a second displacement system PW configured to accurately position the substrate in accordance with certain parameters. The apparatus further includes a projection system (e.g. a refractive projection lens system) PS configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, for directing, shaping, or controlling radiation.

The mask support structure supports, i.e. bears the weight of, the patterning device. It holds the patterning device in a manner that depends on the orientation of the patterning to device, the design of the lithographic apparatus, and other conditions, such as for example whether or not the patterning device is held in a vacuum environment. The mask support structure can use mechanical, vacuum, electrostatic or other clamping techniques to hold the patterning device. The mask support structure may be a frame or a table, for example, which may be fixed or movable as required. The mask support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable minor array of a type as referred to above, or employing a reflective mask).

The lithographic apparatus may be of a type having two (dual stage) or more substrate to tables or “substrate supports” (and/or two or more mask tables or “mask supports”). In such “multiple stage” machines the additional tables or supports may be used in parallel, or preparatory steps may be carried out on one or more tables or supports while one or more other tables or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system Immersion techniques can be used to increase the numerical aperture of projection systems. The term “immersion” as used herein does not mean that a structure, such as a substrate, must be submerged in liquid, but rather only means that a liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing minors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the mask support structure (e.g., mask table MT), and is patterned by the patterning device. Having traversed the mask MA, the radiation beam B passes through the projection system PS, which focuses the beam onto a target portion C of the substrate W. With the aid of the second displacement system PW and position sensor IF (e.g. an interferometric device, linear encoder or capacitive sensor), the substrate table WT can be moved accurately, e.g. so to as to position different target portions C in the path of the radiation beam B. Similarly, the first displacement system PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first displacement system PM. Similarly, movement of the substrate table WT or “substrate support” may be realized using a long-stroke module and a short-stroke module, which form part of the second displacement system PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT or “mask support” and the substrate table WT or “substrate support” are kept essentially stationary, while an entire pattern imparted to the radiation beam is projected onto a target portion C at one time (i.e. a single static exposure). The substrate table WT or “substrate support” is then shifted in the X and/or Y direction so that a different target portion C can be exposed. In step mode, the maximum size of the exposure field limits the size of the target portion C imaged in a single static exposure.

2. In scan mode, the mask table MT or “mask support” and the substrate table WT or “substrate support” are scanned synchronously while a pattern imparted to the radiation beam is projected onto a target portion C (i.e. a single dynamic exposure). The velocity and direction of the substrate table WT or “substrate support” relative to the mask table MT or “mask support” may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT or “mask support” is kept essentially stationary holding a programmable patterning device, and the substrate table WT or “substrate support” to is moved or scanned while a pattern imparted to the radiation beam is projected onto a target portion C. In this mode, generally a pulsed radiation source is employed and the programmable patterning device is updated as required after each movement of the substrate table WT or “substrate support” or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

The displacement system of the lithographic apparatus comprises a first part and a second part which can be displaced with respect to each other in a plane. The first part may comprise a magnet array and the second part an electric coil device cooperating with and moving over the magnet array. The displacement system of the lithographic apparatus may alternatively also be of the moving magnet type in which the coils are stationary and the magnet array is moveable over the coils. The magnet array may be used for movement of the mask table MT in the long-stroke module (coarse positioning) of the first displacement system PM. Similarly, movement of the substrate table WT or “substrate support” may be realized using the magnet array forming a long-stroke module of the second displacement system PW. The magnet array may be used in a so called twin stage concept in which two tables with each their own set of coils may be independently moving over the magnet array. The two tables may be used for two substrate tables, wherein one substrate table can be displaced underneath a projection system while the other is underneath a measurement system.

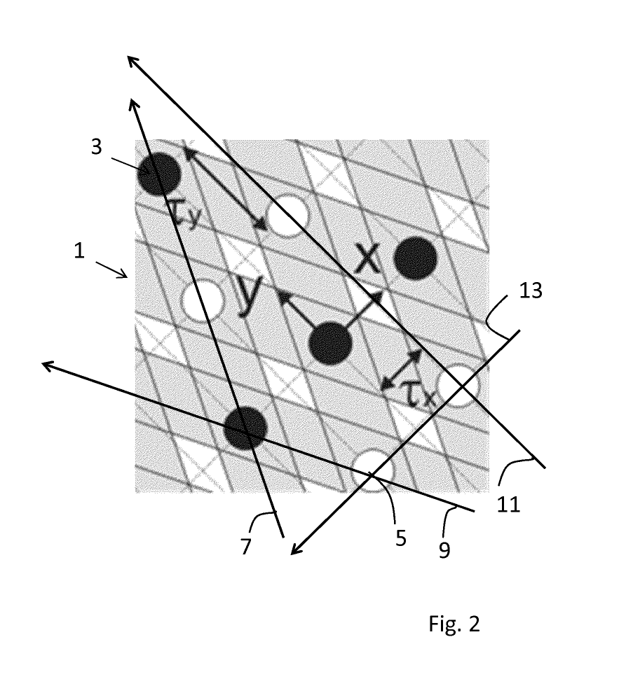

FIGS. 2, 3 and 4 depict a top view on a portion of a magnet array 1 according to an embodiment of the present invention. The magnet array 1 is designed in such a way that it comprises a two dimensional pattern of magnets of a first type 3 (depicted by black dots) and magnets of a second type 5 (depicted by white dots), whereby magnets of the first type and magnets of the second type have an opposing magnetizing direction that is substantially perpendicular to the plane of the array and are alternatingly arranged at regular intervals in both a first direction 7 and a second direction 9 not perpendicular to each other. A distance between the centers of two adjacent magnets of the same type in a third direction 11 is unequal to a distance between the centers of two adjacent magnets of the same type in a fourth direction 13. As depicted the distances are taken from the center of magnets of the first type indicated by the white dots but the same would count for the magnets of the second type indicated by the black dots. In the embodiment as shown, the third 11 and fourth 13 to directions are perpendicular to each other.

In the embodiment as shown, by having the first and second directions 7, 9 not perpendicular to each other, by having a distance between two adjacent magnets of the same type in a third direction 11 unequal to a distance between two adjacent magnets of the same type in a fourth direction 13, and by having the third and fourth directions 7, 9 perpendicular to each other, the magnetic pitch τx in the third direction 7 and the magnetic pitch τy in the fourth direction 9 can be varied without losing the perpendicularity between the magnetic pitches τx and τy. It should however be pointed out that, within the meaning of the present invention, magnet arrays may be applied in which the third 11 and fourth 13 directions are not perpendicular to each other. Such an arrangement may still be found to provide in an improved design flexibility, due to the availability of a different magnetic pitches in the third direction 7 and in the fourth direction 9, even when the perpendicularity between the magnetic pitches τx and τy is lost.

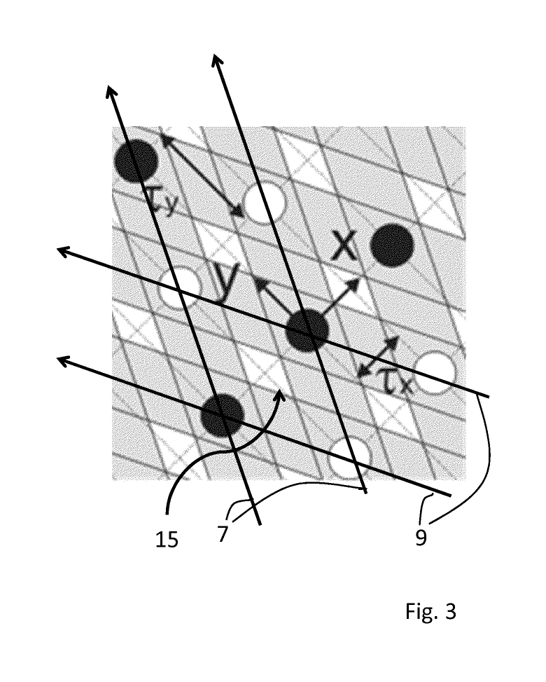

In the embodiment as shown, the magnets of the first type and second type are alternatingly arranged at regular intervals along parallel first lines in the first direction 7 and parallel second lines in the second direction 9, wherein a distance between two neighboring first lines is equal to the distance between two neighboring second lines and two neighboring first lines crossing with two neighboring second lines form a rhombus 15 (see FIG. 3). A normal rhombus is a rhombus without angles of 90 degrees i.e. not being a square.

The first and second directions 7, 9 are configured not perpendicular e.g. preferably under an angle between 89 and 1 degrees, more preferably between 70 and 20 degrees, even more preferably between 55 and 35 degrees and most preferably around 45 degrees.

This allows for a larger design freedom for the design of the displacement system PW, PM. For example the force requirement in the third and fourth direction 7, 9 may be unequal. By varying the magnetic pitches in the third and fourth direction the forces can be altered.

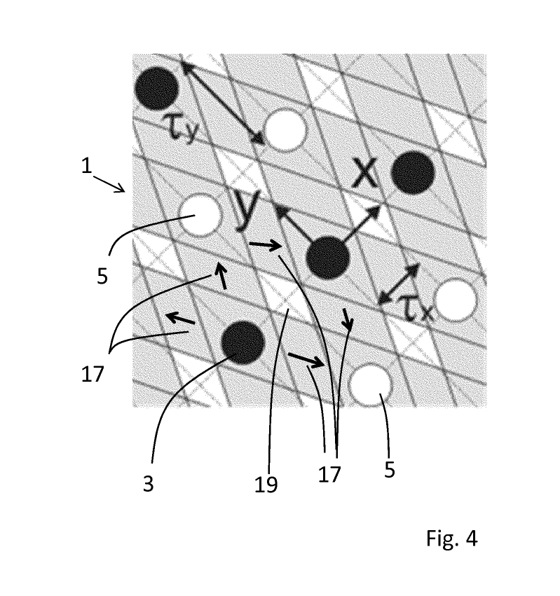

The magnet array may comprises a magnet of a third type 17 (i.e. Halbach magnet) being arranged in the first and second direction between each pair of juxtaposed magnets of the first and the second type 3, 5. The magnet of the third type 17 may have a magnetization direction which extends parallel to the plane of the array 1 (see FIG. 4) to increase the magnetic flux above the magnet array 1. The magnetization direction may preferably be towards the neighboring magnet of the first type (indicated by white dots). The magnets of the first, second and third type 3, 5, 17 may have a parallelogram shape in the plane of the array 1.

The magnets of the first and the second type 3, 5 may have a rhombus shape to more efficiently fil the space in the magnet array 1. The rhombus shape may be identical for magnets of the first and the second type 3, 5 and may have side faces having the same size.

The magnets of the third type 17 may have a parallelogram shape with long and short side faces, wherein the long side face of a magnet of the third type 17 borders with the side face of the magnet of the first or the second type 3, 5, and are just as long as the side faces of the magnet of the first and the second type 3, 5. The short side face of a magnet of the third type 17 is 0.25 to 0.75 the size of the long side face of a magnet of the third type 17.

In between the magnets of the third type 17 and bordering their short side face an area 19 is created with a rhombus shape in the plane. In an embodiment, the area 19 may not be provided with a magnet.

The magnets in the magnet array 1 may be electromagnets and the magnetization direction of the magnets may be altered in accordance with the pattern as specified.

The magnets in the magnet array 1 may be permanent magnets made from a material that is magnetized and creates its own persistent magnetic field. Materials that can be magnetized, which are also the ones that are attracted to a magnet, are called ferromagnetic including iron, nickel, cobalt, some alloys of rare earth metals, and some minerals such as lodestone. The magnets may be cut, sawn or pressed into a required shape.

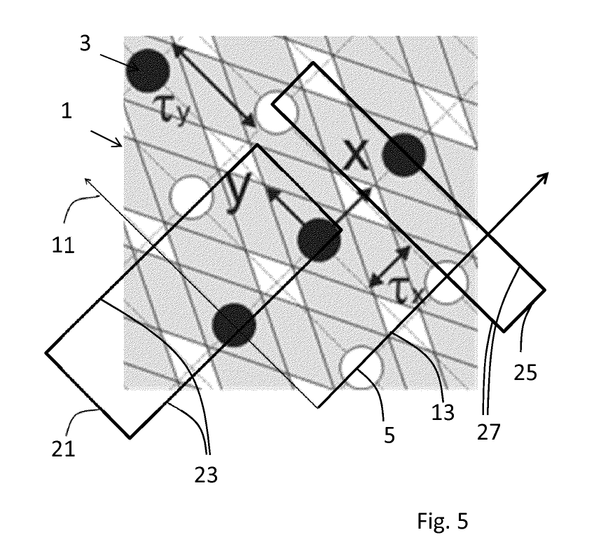

FIG. 5 depicts an electric coil device for a displacement system for use with the magnet array 1. The electric coil device having a first electric coil 21 comprising at least two current conductors 23 to direct current substantially perpendicular to the third direction 11 in opposite directions. Current conductors 23 are spaced apart in the third direction 11 by a first electric coil pitch. The electric coil device having a second electric coil 25 comprising at least two current conductors 27 substantially perpendicular to the fourth direction 13 in opposite directions. Current conductors 27 are spaced apart in the fourth direction with a second electric coil pitch. The first electric coil pitch is unequal to the second electric coil pitch. Current conductors 27 of the second electric coil 25 extend in said third direction 11 and when displaced in said fourth direction 13 will encounter a periodically alternating magnetic flux. When the current conductors 27 are provided with a current, a force is generated between the coil and the magnet array whereby the force in the fourth direction 13 is proportional to the current and to the magnetic flux. The second electric coil pitch of the second electric coil 25 is equal to the magnetic pitch τx which is half the distance between two adjacent magnets of the same type in the fourth direction 13. The first electric coil pitch of the first electric coil 21 is equal to the magnetic pitch τy which is half the distance between two adjacent magnets of the same type in the third direction 11.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer to program stored therein.

The descriptions above are intended to be illustrative, not limiting. Thus, it will be apparent to one skilled in the art that modifications may be made to the invention as described without departing from the scope of the claims set out below.

1.-16. (canceled)

17. A magnet array for a displacement system, the magnet array comprising:
a two dimensional pattern of magnets of a first type and magnets of a second type, wherein the magnets of the first type and the magnets of the second type have an opposing magnetizing direction substantially perpendicular to a plane of the array and are alternatingly arranged at regular intervals in both a first and a second direction in the plane of the array, wherein the first and second directions are not perpendicular to each other,
wherein a distance between two adjacent magnets, both of the first type or both of the second type, in a third direction is unequal to a distance between two adjacent magnets, both of the first type or both of the second type, in a fourth direction.

18. The magnet array of claim 17, wherein the magnets of the first type and second type are alternatingly arranged at regular intervals along parallel first lines in the first direction and parallel second lines in the second direction, wherein a distance between two neighboring first lines is equal to the distance between two neighboring second lines and two neighboring first lines crossing with two neighboring second lines form a rhombus shape.

19. The magnet array of claim 17, wherein the first and second directions are not perpendicular to each other.

20. The magnet array of claim 17, wherein the magnet array comprises magnets of a third type arranged in the first and second direction between each pair of juxtaposed magnets of the first and the second type, wherein the magnets of the third type have a magnetization direction that extends parallel to the plane.

21. The magnet array of claim 17, wherein the magnets of the first and the second type have a same rhombus shape with side faces having the same size.

22. The magnet array of claim 20, wherein the magnets of the third type have a parallelogram shape with long and short side faces, wherein the long side face borders with a side face of the magnet of the first or the second type and are at least as long as side faces of the magnet of the first and the second type.

23. The magnet array of claim 22, wherein the short side face is between about 0.25 to 0.75 the size of the long side face.

24. The magnet array of claim 17, wherein in between the magnets of the third type and bordering their short side face is an area created with a rhombus shape in the plane.

25. The magnet array of claim 24, wherein the area is not provided with a magnet.

26. The magnet array of claim 20, wherein the magnets of the first, second and third type have a parallelogram shape in the plane.

27. The magnet array of claim 17, wherein the third and fourth direction are perpendicular to each other.

28. The magnet array of claim 17, wherein the magnets in the magnet array are electromagnets.

29. A displacement system comprising:
a first part and a second part that are displaced with respect to each other in a plane, wherein the first part comprises the magnet array of claim 17, and the second part is provided with an electric coil device comprising:
at least a first electric coil that has a current conductor substantially perpendicular to the third direction; and
at least a second electric coil that has a current conductor substantially perpendicular to the fourth direction of the magnet array.

30. The displacement system according to claim 29, wherein:
the first electric coil comprises at least two current conductors to direct current substantially perpendicular to the third direction in opposite directions and spaced apart by half the distance between two adjacent magnets of the same type in the third direction; and
the second electric coil comprises at least two current conductors substantially perpendicular to the fourth direction in opposite directions and spaced apart by half the distance between two adjacent magnets of the same type in the fourth direction.

31. A lithographic apparatus arranged to transfer a pattern from a patterning device onto a substrate, wherein the apparatus comprises a magnet array according to claim 17.

32. A device manufacturing method comprising:
transferring a pattern from a patterning device onto a substrate, wherein the method comprises displacing an object table with respect to the patterning device over a plane of a magnet array, the magnet array comprising a two dimensional pattern of magnets of a first type and magnets of a second type, wherein magnets of the first type and magnets of the second type have an opposing magnetizing direction and are alternatingly arranged at regular intervals in both a first and a second direction, the first and second direction being not perpendicular to each other, and a distance between two adjacent magnets of the same type in a third direction being different from a distance between two adjacent magnets of the same type in a fourth direction; and
providing an electrical current, to displace the object table, to at least an electric coil provided to the object table that has current conductors substantially perpendicular to the third or fourth direction.

33. The magnet array of claim 19, wherein the angle is between 70 and 20 degrees,

34. The magnet array of claim 19, wherein the angle is between 55 and 35 degrees.

35. The magnet array of claim 19, wherein the angle is about 45 degrees.
